(19) United States
(12) Patent Application Publication
(10) Pub. No.: US 2025/0316602 A1
(43) Pub. Date: Oct. 9, 2025

(54) HEAT-MITIGATING HIGH-BANDWIDTH DEVICES IN SYSTEM-IN-PACKAGE DEVICES AND ASSOCIATED SYSTEMS AND METHODS

(71) Applicant: Micron Technology, Inc., Boise, ID (US)

(72) Inventors: Lingming Yang, Meridian, ID (US); Raghukiran Sreeramaneni, Frisco, TX (US); Nevil N. Gajera, Meridian, ID (US)

(21) Appl. No.: 19/069,224

(22) Filed: Mar. 4, 2025

Related U.S. Application Data
(60) Provisional application No. 63/575,609, filed on Apr. 5, 2024.

(51) Int. Cl. H01L 23/538; H01L 23/373; H01L 23/48; H01L 25/16

(52) U.S. Cl. CPC H01L 23/5385; H01L 23/3735; H01L 25/16; H01L 23/481

(57) ABSTRACT

System-in-package (SiP) devices, and associated systems and methods are disclosed herein. In some embodiments, a SiP device can include a base substrate, as well as a host device and a heat-mitigating high-bandwidth memory (HBM) device each integrated with the base substrate. The heat-mitigating HBM device can include a stack of one or more memory dies and an interface die carried by the stack of one or more memory dies. The interface die includes an input/output (IO) circuit that is accessible through an upper surface of the interface die. The SiP device can also include a communication substrate carried by the host device and the heat-mitigating HBM device, as well as a thermal interface material carried by the communication substrate. The communication substrate can include one or more communication channels communicably coupling the IO circuit of the interface die to the host device.

### CROSS-REFERENCE TO RELATED APPLICATION(S)

The present application claims priority to U.S. Provisional Patent Application No. 63/575,609, filed Apr. 5, 2024, the disclosure of which is incorporated herein by reference in its entirety.

### TECHNICAL FIELD

The present technology is generally related to vertically stacked semiconductor memory devices and more specifically to systems and methods for managing heat within high-bandwidth memory devices of a system-in-package.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

FIG. 1 is a partially schematic cross-sectional diagram of a system-in-package device.

FIG. 2 is a partially schematic cross-sectional diagram of a system-in-package device configured in accordance with some embodiments of the present technology.

FIG. 3 is a partially schematic cross-sectional diagram of a system-in-package device configured in accordance with some embodiments of the present technology.

FIG. 4 is a partially schematic cross-sectional diagram of a system-in-package device configured in accordance with further embodiments of the present technology.

FIG. 5 is a flow diagram of a process for manufacturing a system-in-package device in accordance with some embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, vertically stacked memory devices have been introduced, often referred to as 2.5-dimensional (“2.5D”) memory devices when placed adjacent to a host device or 3-dimensional (“3D”) memory devices when stacked on top of the host device. Some 2.5D or 3D memory devices are formed by stacking memory dies vertically, and interconnecting the dies using through-silicon (or through-substrate) vias (TSVs). Benefits of the 2.5D and 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5D and 3D memory devices contribute to higher memory access speed, lower power consumption, and chip size reduction. Example 2.5D and/or 3D memory devices include Hybrid Memory Cube (HMC) and High-Bandwidth Memory (HBM) devices. For example, HBM devices are a type of memory that includes a vertical stack of dynamic random-access memory (DRAM) dies and an interface die (which, e.g., provides the interface between the DRAM dies of the HBM device and a host device).

In a system-in-package (SiP) configuration, HBM devices may be integrated with a host device (e.g., a graphics processing unit (GPU), a computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between the host device and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU/TCU) and HBM devices during operation. For example, the high-bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system.

Market demands on SiP devices and/or the HBM devices therein can present certain challenges, however. One such challenge is that demands on SiP devices (and the HBM devices therein) require the devices to continually increase in functionality while decreasing in package size, thereby increasing power density within the SiP device. As a result, as discussed in more detail below, traffic-heavy circuits in the HBM devices, such as input/output (“IO”) circuits in an interface die, can generate significant amounts of heat. If not mitigated, the heat can cause various deleterious effects on the HBM device, such as the degradation of communication channels, increased memory loss (requiring increased refresh rates and therefore more power), and/or the like. The systems and methods described herein help address heat within the HBM devices and/or within the SiP devices more generally. For example, the SiP devices described herein are configured to mitigate the thermal demands by arranging the SiP device and/or components therein (e.g., the HBM devices, host devices, and/or the like) to place heat-generating components (e.g., the IO circuits) closer to heat-dissipating materials, such as a thermal interface material. In some embodiments, a heat-mitigating SiP, a heat-mitigating HBM device, and/or a host device for use with a heat-mitigating HBM device is arranged so that various heat-generating components (e.g., IO circuits), are located at an upper-portion of the device that is closer to a thermal-interface material.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Further, although primarily discussed herein in the context of heat-mitigating HBM devices for SiP devices, one of skill in the art will understand that the scope of the invention is not so limited. For example, various components of the SiP devices described herein can also be implemented in various other stacked semiconductor devices to help mitigate the deleterious effects of heat therein. Accordingly, the scope of the invention is not confined to any subset of embodiments and is confined only by the limitations set out in the appended claims.

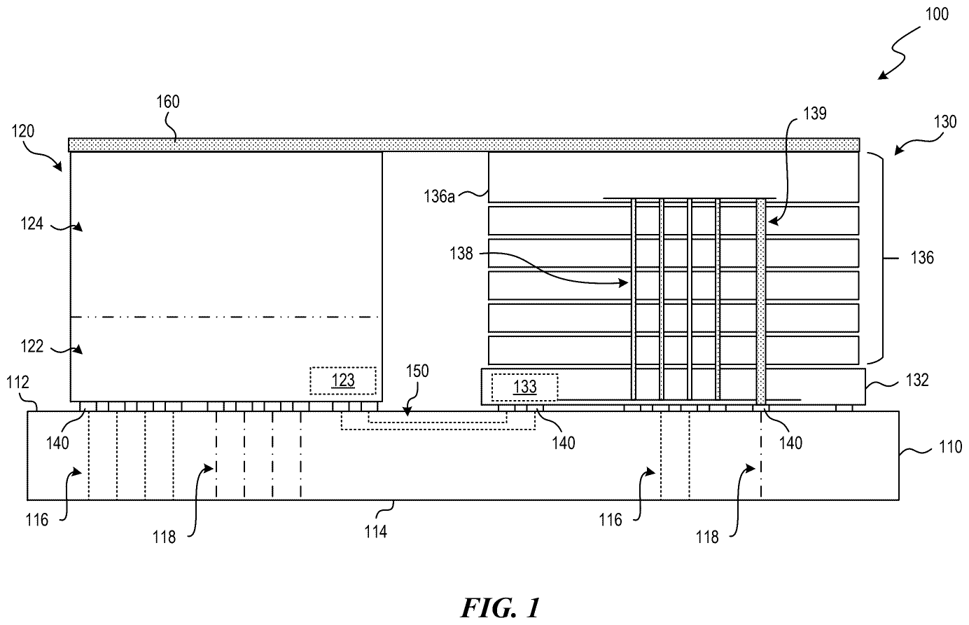

FIG. 1 is a partially schematic cross-sectional diagram of a SiP device 100. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110 (sometimes referred to as a SiP bus). The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source.

In the illustrated environment, the host device 120 includes a host processor 122 and a host substrate 124 (e.g., a silicon substrate) on which the host processor 122 is formed. The host processor 122 can include a variety of components, such as a processing unit (e.g., CPU/GPU/TCU), one or more registers, one or more cache memories, and/or a variety of other components. For example, in the illustrated environment, the host processor 122 includes a host IO circuit 123 that can direct signals to and/or from the HBM device 130 through the communication channels 150. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory dies 136 (six illustrated in FIG. 1) carried by the interface die 132. The HBM device 130 also includes one or more signal TSVs 138 (four illustrated in FIG. 1) and one or more power TSVs 139 (one illustrated in FIG. 1) each extending from the interface die 132 to an uppermost memory die 136a. The power TSV(s) 139 provide power (e.g., received from one or more of the external power TSVs 118) to the interface die 132 and each of the memory dies 136. The signal TSVs 138 communicably couple each of the memory dies 136 to an IO circuit 133 in the interface die 132 (in addition to various other circuits in the interface die 132). In turn, the IO circuit 133 can direct signals to and/or from the host device 120 and/or an external component (e.g., an external storage device coupled to one or more of the external signal TSVs 116 and/or the like).

As further illustrated in FIG. 1, the SiP device 100 also includes a thermal interface material 160 carried by the host device 120 and the HBM device 130. The thermal interface material 160 can help dissipate heat away from the host device 120 and the HBM device 130 during operation of the SiP device 100 to help reduce the deleterious effects of heat. However, demands on SiP devices have required the HBM devices therein (e.g., the HBM device 130) to shrink in size and increase in responsiveness. As a result, the space dedicated for the IO circuit 133 in the interface die 132 has shrunk while the number of signals the IO circuit 133 must handle has increased. In turn, these changes have increased the power density in the IO circuit 133, thereby increasing the temperature in the interface die 132. This increase in the operating temperature can exceed acceptable operational levels for the HBM device 130, threatening to undermine the operation of the HBM device 130 (e.g., undermining data retention rates, requiring increased refresh rates, and/or the like) and/or connections within the SiP device 100 (e.g., breaking connections between the HBM device 130 and the base substrate 110, breaking connections in the signal TSVs 138, damaging circuits in the interface die 132 and/or the memory dies 136, and/or the like).

Heat-mitigating HBM devices, and/or heat-mitigating SiP devices (having host devices for use with heat-mitigating HBM devices), and related systems and methods that address the shortcomings discussed above are disclosed herein. For example, as discussed in more detail below, a heat-mitigating SiP device according to the present technology can include a base substrate, as well as a heat-mitigating HBM device and a host device for use with the heat-mitigating HBM device integrated with the base substrate. The heat-mitigating HBM device can include a stack of one or more memory dies and an interface die that is carried by the stack of memory dies. Further, the interface die can include an IO circuit that is accessible through an upper surface of the interface die (and/or an uppermost surface of the HBM device). Said another way, in some embodiments, the heat-mitigating HBM device moves the IO circuit closer to an outer surface of the heat-mitigating SiP device, and therefore closer to a thermal interface material, to help increase the amount of heat that can be transferred away from the IO circuit by the thermal interface material.

As also discussed in more detail below, the heat-mitigating SiP device can also include an upper substrate (sometimes referred to herein as a “communication substrate,” an “upper interposer,” a “signal interposer,” a “signal substrate,” and/or the like) carried by the host device and the heat-mitigating HBM device. The communication substrate includes one or more communication channels that communicably couple the upper surface of the interface die to the host device. That is, the communication channels in the communication substrate can communicably couple a host IO circuit to the IO circuit in the interface die through a topmost surface of the host device and the uppermost surface of the HBM device.

The position of the communication channels above the host device and the heat-mitigating HBM device can help reduce a total length of communication channels (e.g., including any TSVs in the host device and/or the heat-mitigating HBM device) between the host IO circuit and the IO circuit in the interface die. In turn, the reduction in length can reduce the power required to send signals between the host IO circuit and the IO circuit in the interface die, thereby reducing the heat produced in each of the IO circuits. Additionally, or alternatively, the reduction in length can help increase a bandwidth of the communication channels between the host IO circuit and the IO circuit in the interface die. Further, the position of the communication channels above the heat-mitigating HBM device can eliminate a need for the IO circuit in the interface die to be coupled to the host device through the base substrate. As a result, the HBM device can omit one or more signal TSVs that would otherwise be required to communicably couple the host IO circuit and the IO circuit in the interface die. The omission can help reduce manufacturing costs, increase space available for other circuits (e.g., DRAM circuits) in the memory dies, and/or reduce the footprint of the HBM device.

In some embodiments, the host device includes a processing unit that is carried by the base substrate and a host device substrate carried by the processing unit. The host IO circuit can be a component of the processing unit that is coupled to one or more signal TSV segments in the host device substrate. Further, the heat-mitigating SiP device can include an IO die carried by the host device and positioned between the host device and the communication substrate. The IO die can include an intermediate IO circuit that is communicably coupled to the host IO circuit by one or more signal TSV segments in the IO die that are each coupled to a corresponding one of the signal TSV segments in the host device substrate. That is, the intermediate IO circuit is communicably coupled between the host IO circuit and the communication channels in the communication substrate. By including an intermediate IO circuit, the heat-mitigating SiP device can reduce the power required to send signals between the host IO circuit and the IO circuit in the interface die with minimal modifications to the host device.

In some embodiments, the host device includes a host device substrate that is carried by the base substrate and a processing unit that is carried by the host device substrate. In such embodiments, the host IO circuit can be a component of the processing unit that is directly accessible through a top surface of the processing unit (and/or a topmost surface of the host device. As a result, the communication channels in the communication substrate can be communicably coupled directly to the top surface of the processing unit (and therefore the host IO circuit), thereby reducing a distance between the host IO circuit and the IO circuit in the interface die. In some such embodiments, the host device substrate includes a plurality of TSVs extending from a lowermost surface of the host device to a metallization layer within the processing unit to route signals between the base substrate and the processing unit.

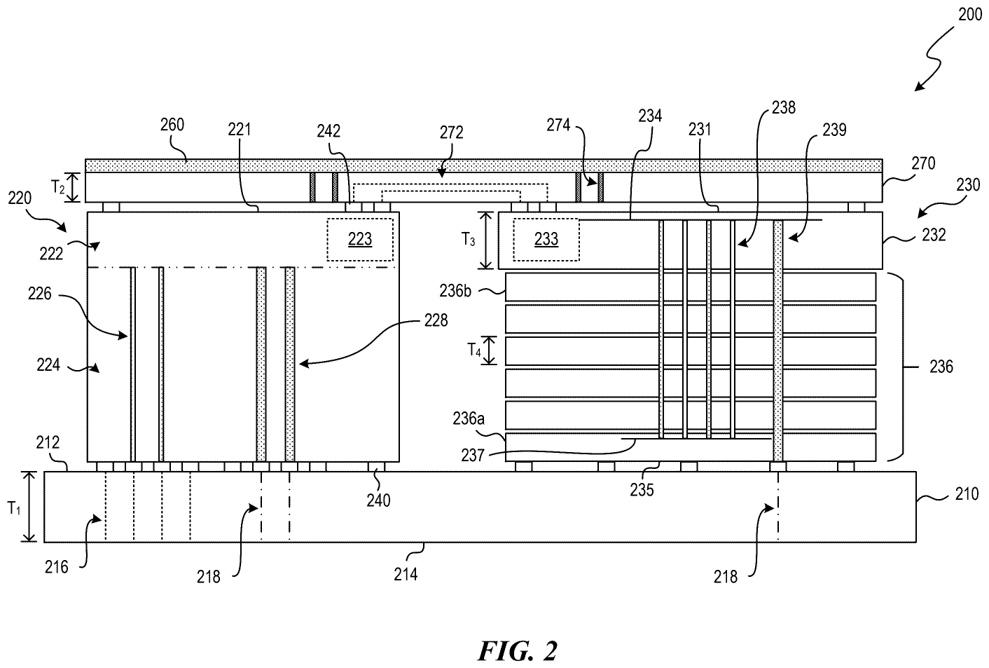

Additional details on the heat-mitigating SiP device, components thereof, and related systems and methods are discussed below with reference to FIGS. 2-5.

FIG. 2 is a partially schematic cross-sectional diagram of a heat-mitigating SiP device 200 configured in accordance with some embodiments of the present technology. As illustrated in FIG. 2, the heat-mitigating SiP device 200 (“SiP device 200”) can include a base substrate 210, as well as a heat-mitigating HBM device 230 and host device 220 for use with the heat-mitigating HBM device 230 each integrated with (e.g., carried by and coupled to) an upper surface 212 of the base substrate 210 by interconnect structures 240. The base substrate 210 can include one or more external signal TSVs 216 (four illustrated in FIG. 2) and one or more external power TSVs 218 extending between the upper surface 212 (sometimes also referred to herein as an “active surface”) and a lower surface 214 of the base substrate 210. The external signal TSVs 216, via the interconnect structures 240, allow the host device 220 and the heat-mitigating HBM device 230 to receive signals from (and send signals to) another component coupled to the lower surface 214 of the base substrate 210 (e.g., from another controller coupled to a PCB the SiP device 200 is coupled to and/or the like). Similarly, the external power TSVs 218, via the interconnect structures 240, allow the host device 220 and the heat-mitigating HBM device 230 to receive power from another component coupled to the lower surface 214 of the base substrate 210 (e.g., from the PCB the SiP device 200 is coupled to and/or the like).

As further illustrated in FIG. 2, each of the IO circuits in the SiP device 200 have been positioned closer to an outer surface of the SiP device 200 as compared to the SiP device 100 discussed above with reference to FIG. 1. For example, the host device 220 includes a host substrate 224 integrated with the base substrate 210 and a host processor 222 formed on and/or carried by the host substrate 224. The host processor 222 (sometimes referred to herein as a “processing unit” and/or the like) can include a GPU, CPU, TCU, one or more registers, one or more levels of cache memory, and/or any other suitable component. Further, as illustrated in FIG. 2, the host processor 222 can include a host IO circuit 223 that is accessible through a topmost surface 221 of the host device 220 (e.g., a top surface of the host processor 222).

Similarly, the heat-mitigating HBM device 230 includes a die stack having a plurality of memory dies 236 that includes a lowermost memory die 236a that is integrated with the base substrate 210 and an uppermost memory die 236b opposite the lowermost memory die 236a. The heat-mitigating HBM device 230 also includes an interface die 232 that is integrated with the uppermost memory die 236b. The interface die 232 includes an IO circuit 233 that is accessible through an uppermost surface 231 of the heat-mitigating HBM device 230 (e.g., an upper surface of the interface die 232). As a result, the IO circuit 233 in the interface die 232 can be communicably coupled to the host IO circuit 223 through communication channels carried above the host device 220 and the heat-mitigating HBM device 230.

In the illustrated embodiments, for example, the SiP device 200 also includes an upper substrate 270 integrated with (e.g., carried by and coupled to) the topmost surface 221 of the host device 220 and the uppermost surface 231 of the heat-mitigating HBM device 230. In various embodiments, the upper substrate 270 (sometimes also referred to herein as a “communication substrate,” an “upper interposer,” a “signal substrate,” a “signa interposer,” and/or the like) can be a silicon interposer, a PCB component, a plurality of dielectric layers (and/or other suitable materials) formed in back-end-of-line (BEOL) processing while forming the SiP device 200, and/or various other suitable substrates. Because the upper substrate 270 does not provide structural support for the host device 220 and/or the heat-mitigating HBM device 230, however, the upper substrate 270 can be thinner than the base substrate 210. That is, while the base substrate 210 has a first thickness T₁, the upper substrate can have a second thickness T₂ that is smaller than the first thickness T₁. As a result, the upper substrate 270 does not significantly increase an overall height of the SiP device 200.

In the illustrated embodiments, the upper substrate 270 is integrated with the host device 220 and the heat-mitigating HBM device 230 through one or more upper interconnect structures 242. The upper interconnect structures 242 can be solder structures (e.g., solder balls), metal-metal bonds, and/or any other suitable conductive structure coupled between the upper substrate 270 and one or more bond pads (not shown in the schematic cross-section of FIG. 2) on each of the topmost surface 221 of the host device 220 and the uppermost surface 231 of the heat-mitigating HBM device 230. The bond pads and the upper interconnect structures 242 can couple the host IO circuit 223 and the IO circuit 233 in the interface die 232 to one or more communication channels 272 (two illustrated in FIG. 2) formed in the upper substrate 270. Said another way, the communication channels 272 in the upper substrate 270 can communicably couple the host IO circuit 223 to the IO circuit 233 in the interface die 232 to route signals between the host device 220 and the heat-mitigating HBM device 230.

As a result, as illustrated in FIG. 2, the IO circuit 233 in the interface die 232 can be positioned significantly closer to a thermal interface material 260 as compared to, for example, the IO circuit 133 in the interface die 132 of FIG. 1. Because the IO circuit 233 in the interface die 232 is typically the hottest spot in the SiP device 200 (or one of the hottest spots) during operation, the closer proximity to the thermal interface material 260 can help dissipate heat away from the SiP device 200. Additionally, heat from the IO circuit 233 does not need to be communicated through multiple layers of die substrates (e.g., silicon, dielectrics, and/or the like that are relatively non-thermally conductive) before reaching the thermal interface material 260, thereby reducing thermal resistance between the IO circuit 233 and the thermal interface material 260. The reduction in thermal resistance can allow the IO circuit 233 to communicate significantly more heat to the thermal interface material 260 for dissipation. Further, in some embodiments, the upper substrate 270 includes thermal TSVs 274 that are positioned to help communicate heat through the upper substrate 270. The thermal TSVs 274 can include a variety of conductive materials and can be formed adjacent to the IO circuit 233 and/or the host IO circuit 223 to provide a heat path between the host device 220 and the thermal interface material 260 and/or between the heat-mitigating HBM device 230 and the thermal interface material 260. In turn, the dedicated heat paths can help increase the amount of heat transferred to the thermal interface material 260 from the host IO circuit 223 and/or the IO circuit 233. Each of the improvements discussed above can help reduce the operational temperature of the heat-mitigating HBM device 230 as compared to, for example, the HBM device 130 of FIG. 1. The reduction in operation temperatures, in turn, can help improve the operation of the SiP device 200 (e.g., requiring lower refresh rates, improving data retention, extending a lifetime of components of the SiP device 200, and/or the like).

The relocation of the host IO circuit 223 and the IO circuit 233 in the interface die 232, however, can also allow (or require) various additional changes to the base substrate 210, the host device 220, and/or the heat-mitigating HBM device 230. For example, as further illustrated in FIG. 2, the host device 220 can include a plurality of signal TSVs 226 and a plurality of power TSVs 228 extending through the host substrate 224 to the host processor 222. The signal TSVs 226 and the power TSVs 228 can couple the host processor 222 to the base substrate 210. More specifically, the signal TSVs 226 can couple the host processor 222 to one or more of the external signal TSVs 216 in the base substrate 210 to receive signals (e.g., data, instructions, processing commands, and/or the like) through the base substrate 210. Similarly, the power TSVs 228 couple the host processor 222 to one or more of the external power TSVs 218 in the base substrate 210 to receive power through the base substrate 210.

In a related example, as further illustrated in FIG. 2, the heat-mitigating HBM device 230 can include a variety of TSVs that are modified for the relocation of the interface die 232. For example, the heat-mitigating HBM device 230 can include a plurality of signal TSVs 238 that extend from a first metallization layer 234 in the interface die 232 to a second metallization layer 237 in the lowermost memory die 236a. Said another way, the signal TSVs 238 extend from the first metallization layer 234 in the interface die 232 to an intermediate depth in the lowermost memory die 236a. The first metallization layer 234, in turn, is coupled to the IO circuit 233 in the interface die 232. As a result, the signal TSVs 238 communicably couple each of the memory dies 236 to the IO circuit 233 in the interface die 232 (and/or various other suitable components of the interface die 232). The communicable coupling, in turn, allows the IO circuit 233 to route signals (e.g., read and write commands) between the host device 220 and each of the memory dies 236 in the die stack.

Additionally, the heat-mitigating HBM device 230 can include one or more power TSVs 239 (one illustrated in FIG. 2) that extend from a lowermost surface 235 of the heat-mitigating HBM device 230 (e.g., a lower surface of the lowermost memory die 236a) to an intermediate depth in the interface die 232. For example, in the illustrated embodiments, the power TSV 239 extends to the first metallization layer 234 in the interface die 232. Because the power TSV(s) 239 extend to the lowermost surface 235 of the heat-mitigating HBM device, the power TSV(s) 239 can be communicably coupled to one or more of the external power TSVs 218 in the base substrate 210 to receive power through the base substrate 210.

In the illustrated embodiments, the signal TSVs 238 are not coupled to the base substrate 210 through the lowermost surface 235 of the heat-mitigating HBM device 230. Instead, only the power TSV(s) 239 extend to the lowermost surface 235. Further, because the host device 220 and the heat-mitigating HBM device 230 are communicably coupled by the upper substrate 270, the base substrate 210 does not include communication channels between the host device 220 and the heat-mitigating HBM device 230. In some embodiments, the absence of the communication channels allows the base substrate 210 to be a prepreg substrate and/or another PCB substrate (e.g., instead of a silicon substrate), which can help lower a cost of manufacturing the SiP device 200. In some embodiments, the absence of the communication channels between the host device 220 and the heat-mitigating HBM device 230 provides space for communication channels to be formed connecting to another HBM device (e.g., another row of HBM devices). The additional communication channels can help expand the memory (or storage) available within the SiP device 200, thereby expanding the functionality of the SiP device 200.

As further illustrated in FIG. 2, the relocation of the interface die 232 to the top of the heat-mitigating HBM device 230 can allow the interface die 232 to be used for height matching. For example, the interface die 232 can have a third thickness T₃ that is selected to match the overall height of the heat-mitigating HBM device 230 to the overall height of the host device 220. Further, because the interface die 232 is used for height matching, each of the memory dies 236 can have a generally uniform fourth thickness T₄, allowing each of the memory dies 236 to be produced by the same manufacturing process. In the illustrated embodiment, the third thickness T₃ is larger than the generally uniform fourth thickness T₄. The standardization of the thickness of the memory dies 236 can increase throughput in the manufacturing process for the memory dies 236 and/or reduce costs associated with manufacturing the memory dies 236.

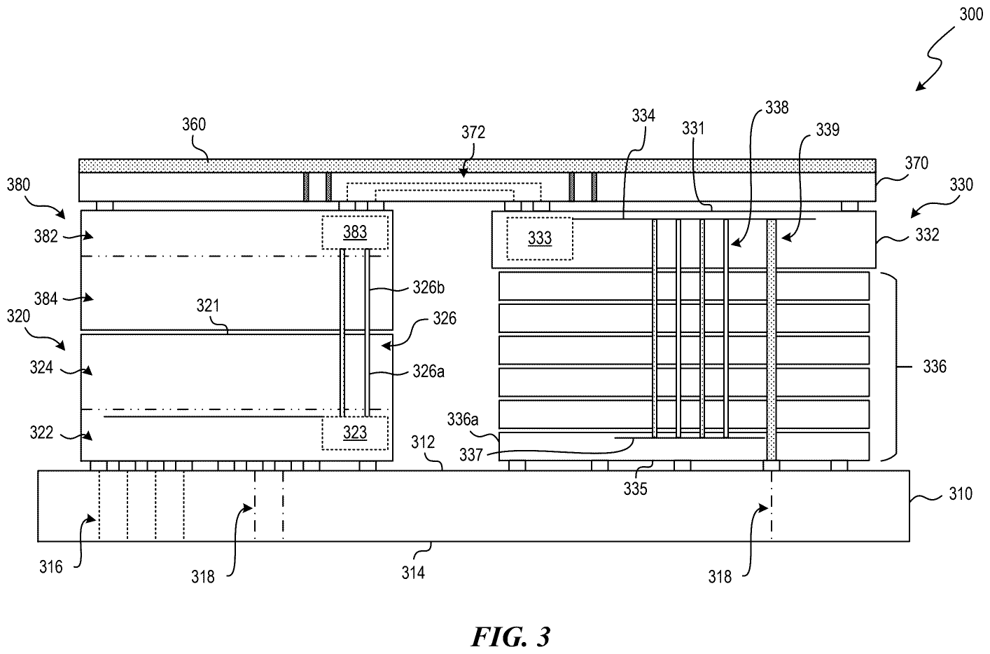

FIG. 3 is a partially schematic cross-sectional diagram of a heat-mitigating SiP device 300 configured in accordance with some embodiments of the present technology. As illustrated in FIG. 3, the heat-mitigating SiP device 300 (“SiP device 300”) is generally similar to the SiP device 200 described above with reference to FIG. 2. For example, the SiP device 300 of FIG. 3 includes a base substrate 310 as well as a heat-mitigating HBM device 330 and a host device 320 for use with the heat-mitigating HBM device 330 each integrated with (e.g., carried by and coupled to) an upper surface of the base substrate 310. The base substrate 310 includes a plurality of external signal TSVs 316 and a plurality of external power TSVs 318 each extending from the upper surface 312 of the base substrate 310 to a lower surface 314 of the base substrate 310. The host device 320 is coupled to one or more of the external signal TSVs 316 and one or more of the external power TSVs 318. The heat-mitigating HBM device 330 is coupled to one or more of the external power TSVs 318.

Further, the heat-mitigating HBM device 330 includes a die stack having one or more memory dies 336 (six shown in FIG. 3) and an interface die 332 carried by the memory dies 336. The interface die 332 includes an IO circuit 333 that is accessible through an uppermost surface 331 of the heat-mitigating HBM device 330 (e.g., an upper surface of the interface die 332). The heat-mitigating HBM device 330 also includes a plurality of signal TSVs 338 extending from a first metallization layer 334 in the interface die to a second metallization layer 337 in a lowermost memory die 336a, as well as one or more power TSVs 339 (one illustrated in FIG. 3) extending from a lowermost surface 335 of the heat-mitigating HBM device 330 to the first metallization layer 334 (or another suitable layer in the interface die 332).

Still further, the SiP device 300 includes an upper substrate 370 carried by the host device 320 and the heat-mitigating HBM device 330, as well as a thermal interface material 360 carried by the upper substrate 370. The upper substrate 370 includes one or more communication channels 372 (two illustrated in FIG. 3) that can communicably couple the host device 320 to the heat-mitigating HBM device 330 (e.g., to communicably couple a host IO circuit 323 to the IO circuit 333 in the interface die 332).

As illustrated in FIG. 3, however, the host device 320 includes a host processor 322 carried by the base substrate 310 and a host substrate 324 carried by the host processor 322. The host processor 322 includes the host IO circuit 323, as well as various other electronic components (e.g., a GPU/CPU/TCU, one or more registers, one or more cache memories, and/or the like). In the illustrated embodiments, the host processor 322 can be directly coupled to one or more of the external signal TSVs 316 and one or more of the external power TSVs 318 in the base substrate 310. The illustrated position of the host IO circuit 323, however, requires conductive features (e.g., TSVs) to couple the host IO circuit to an uppermost surface 321 of the host device 320. Further, the illustrated position of the host IO circuit 323 can require a relatively long overall communication path between the host IO circuit 323 and the IO circuit 333 in the heat-mitigating HBM device 330.

Accordingly, as further illustrated in FIG. 3, the SiP device 300 can also include an IO die 380 carried by the host device 320 and positioned between the host device 320 and the upper substrate 370. The IO die 380 can include a substrate backing 384 and an active layer 382 carried by the substrate backing 384. The active layer 382 includes an intermediate IO circuit 383 that is communicably coupled to the host IO circuit 323. For example, in the illustrated embodiment, the host IO circuit 323 and the intermediate IO circuit 383 are communicably coupled by one or more routing TSVs 326 (two illustrated in FIG. 3). Each of the routing TSVs 326 have a first segment 326a formed in the host device 320 and a second segment 326b formed in the IO die 380 and communicably coupled to a corresponding one of the first segments 326a. Further, the intermediate IO circuit 383 is communicably coupled between the host IO circuit 323 and the communication channels 372 in the upper substrate 370. Said another way, the intermediate IO circuit 383 is communicably coupled between the host IO circuit 323 and the IO circuit 333 in the interface die 332. As a result, the intermediate IO circuit 383 can act as a midpoint between the host IO circuit 323 and the IO circuit 333 in the interface die 332, thereby reducing the power (and/or channel width) required to send signals between the host IO circuit 323 and the IO circuit 333 in the interface die 332.

In the embodiments illustrated in FIG. 3, the host device 320 and the IO die 380 are illustrated as separate components that are both stacked on the base substrate 310. However, it will be understood that the technology is not so limited. In some embodiments, the host device 320 and the IO die 380 are formed as a single component that is integrated with the base substrate 310. For example, the components forming the host processor 322 can be formed on a first side of the host substrate 324 while the components of the active layer 382 are formed on a second side of the host substrate 324 opposite the first side. In such embodiments, the host IO circuit 323 and the intermediate IO circuit 383 can be communicably coupled by one or more TSVs (and/or one or more metallization layers) extending through the host substrate 324. Said another way, the IO die 380 can be formed as an integral part of the host device 320 rather than a separate component.

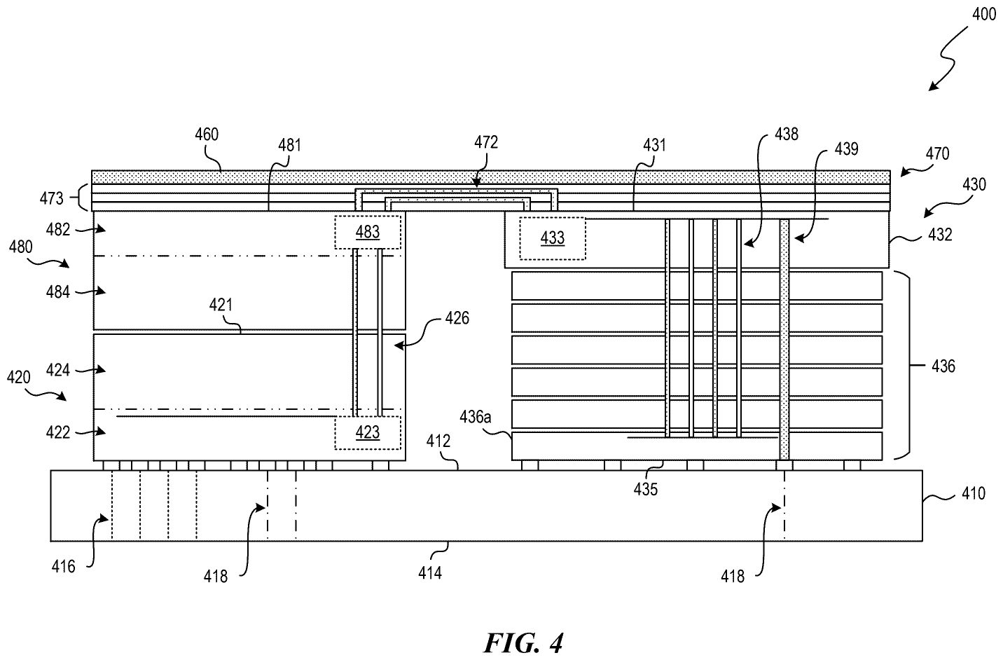

FIG. 4 is a partially schematic cross-sectional diagram of a heat-mitigating SiP device 400 configured in accordance with further embodiments of the present technology. As illustrated in FIG. 4, the heat-mitigating SiP device 400 (“SiP device 400”) is generally similar to the SiP device 300 described above with reference to FIG. 3. For example, the SiP device 400 of FIG. 4 includes a base substrate 410, as well as a heat-mitigating HBM device 430 and a host device 420 for use with the heat-mitigating HBM device 430 each integrated with (e.g., carried by and coupled to) an upper surface of the base substrate 410 and an IO die 480 integrated with an uppermost surface 421 of the host device 420. The base substrate 410 includes a plurality of external signal TSVs 416 and a plurality of external power TSVs 418 each extending from the upper surface 412 of the base substrate 410 to a lower surface 414 of the base substrate 410. The host device 420 is coupled to one or more of the external signal TSVs 416 and one or more of the external power TSVs 418. The heat-mitigating HBM device 430 is coupled to one or more of the external power TSVs 418.

The host device 420 includes a host processor 422 integrated with the base substrate 410 and a host substrate 424 carried by the host processor 422. The host processor 422 includes, among other features, a host IO circuit 423. The IO die 480 includes a substrate backing 484 and an active layer 482 carried by the substrate backing 484. The active layer 482 includes an intermediate IO circuit 483 that is communicably coupled to the host IO circuit 423 via one or more routing interconnects 426 (two illustrated in FIG. 4). Further, the heat-mitigating HBM device 430 includes a die stack having one or more memory dies 436 (six shown in FIG. 4) and an interface die 432 carried by the memory dies 436. The interface die 432 includes an IO circuit 433 that is accessible through an uppermost surface 431 of the heat-mitigating HBM device 430 (e.g., an upper surface of the interface die 432). The heat-mitigating HBM device 430 also includes a plurality of signal TSVs 438 extending from the interface die to an intermediate location in a lowermost memory die 436a, as well as one or more power TSVs 439 (one illustrated in FIG. 4) extending from a lowermost surface 435 of the heat-mitigating HBM device 430 to the interface die 432.

Still further, the SiP device 400 includes an upper substrate 470 carried by the host device 420 and the heat-mitigating HBM device 430 and a thermal interface material 460 carried by the upper substrate 470. The upper substrate 470 includes one or more communication channels 472 (two illustrated in FIG. 4) that can communicably couple the IO circuit 433 to the intermediate IO circuit 483, thereby coupling the IO circuit 433 to the host IO circuit 423 without any communication channels in the base substrate 410.

In the illustrated embodiments, however, the upper substrate 470 includes a plurality of substrate layers 473 (three illustrated in FIG. 4) that are formed over an uppermost surface 431 of the heat-mitigating HBM device 430 and a topmost surface 481 of the IO die 480. The substrate layers 473 can be dielectric layers, insulation layers, silicon layers, and/or any other suitable substrates. Further, the substrate layers 473 and the communication channels 472 (e.g., metal route lines) can be formed during BEOL processing on the SiP device 400. Purely by way of example, the SiP device 400 can be constructed during a wafer-level process adjacent to one or more additional SiP devices. After the host device 420, the heat-mitigating HBM device 430, and the IO die 480 are stacked on the base substrate 410 (in wafer form), various BEOL processes may be performed to deposit the substrate layers 473 and form the communication channels 472 therein. The manufacturing process can then form the thermal interface material 460 over the upper substrate 470 and/or attach the thermal interface material 460 to the upper substrate 470. In embodiments where the BEOL processing happens at the wafer-level, the manufacturing process can then singulate the SiP device 400 from the other SiP devices on the wafer.

Forming the substrate layers 473 and the communication channels 472 in BEOL processes on the SiP device 400 can help reduce the cost associated with manufacturing the SiP device 400. For example, the BEOL processing can be cheaper than producing the upper substrate 470 as a separate substrate and then attaching the separate substrate, particularly when the substrate layers 473 are cheaper (e.g., a dielectric material) compared to the materials in a separate substrate (e.g., a silicon interposer). Additionally, or alternatively, the BEOL processing can help increase throughput while manufacturing the SiP device 400, especially when the BEOL processing occurs at the wafer-level.

Although FIG. 4 illustrates the upper substrate 470 that includes a plurality of layers with respect to an embodiment of the SiP device 400 that includes the IO die 480, it will be understood that the technology disclosed herein is not so limited. For example, a layered upper substrate of the type illustrated in FIG. 4 can be implemented in the SiP device 200 discussed above with reference to FIG. 2. In such embodiments, the BEOL processes can form the upper substrate 470 of FIG. 4 over the host device 220 and the heat-mitigating HBM device 230 of FIG. 2.

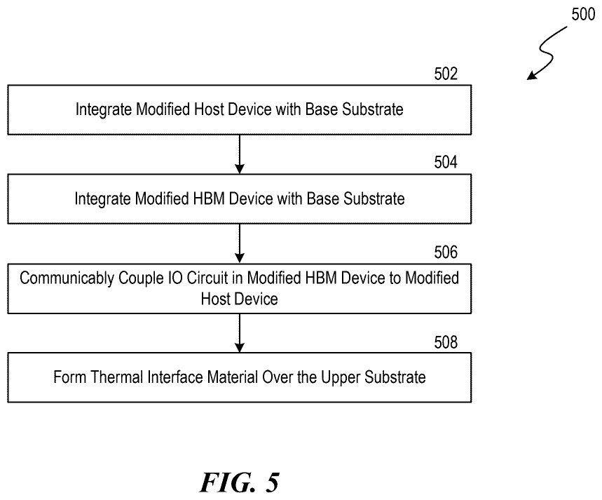

FIG. 5 is a flow diagram of a process 500 for manufacturing a heat-mitigating SiP device in accordance with some embodiments of the present technology. The process 500 can be implemented by a single manufacturing apparatus and/or split between multiple manufacturing apparatuses to construct heat-mitigating SiP devices according to the embodiments discussed above.

The process 500 begins at block 502 by integrating a host device with a base substrate of the heat-mitigating SiP device. In various embodiments, the base substrate can be a silicon interposer, a substrate of organic material, a substrate of inorganic material, and/or any other suitable material that provides external connections to the host device and/or provides mechanical support for the components of a heat-mitigating SiP device. Integrating the host device with the base substrate can include bonding the host device to the base substrate via one or more interconnect structures (e.g., solder structures, conductive posts, and/or the like) and/or forming one or more metal-metal bonds directly between bond pads in the base substrate and bond pads in the host device. In some embodiments, the process 500 at block 502 also includes integrating an IO die (e.g., the IO die 380 of FIG. 3) with a topmost surface of the host device. Similar to the integration with the base substrate, the IO die can be integrated with the host device by one or more interconnect structures and/or direct metal-metal bonds between conductive features in the IO die and the host device.

At block 504, the process 500 includes integrating a heat-mitigating HBM device with the base substrate. Similar to the discussion above, integrating the heat-mitigating HBM device with the base substrate can include bonding the heat-mitigating HBM device to the base substrate via one or more interconnect structures and/or forming one or more metal-metal bonds directly between bond pads in the base substrate and bond pads in the heat-mitigating HBM device. In some embodiments, the process 500 can execute block 504 before executing all (or some of) block 502 to integrate the heat-mitigating HBM device with the base substrate before integrating the host device with the base substrate and/or before integrating the IO die with the host device. In some embodiments, the process 500 can execute block 504 at generally the same time as block 502 to integrate the host device and the heat-mitigating HBM device with the base substrate at generally the same time.

At block 506, the process 500 includes communicably coupling an IO circuit in the heat-mitigating HBM device (e.g., the IO circuit 233 in the interface die 232 of FIG. 2) to the host device (e.g., to the host IO circuit 223 of FIG. 2). As discussed in more detail above, the communicable coupling can be accomplished through one or more communication channels in an upper substrate carried by an upper surface of the heat-mitigating HBM device and an upper surface of the host device. In some embodiments, block 506 includes integrating an upper substrate (e.g., a silicon interposer and/or another suitable substrate) with the communication channels with the upper surface of the heat-mitigating HBM device and the upper surface of the host device. In such embodiments, similar to the discussion above, integrating the upper substrate with the heat-mitigating HBM device and the host device can include bonding the upper substrate to the heat-mitigating HBM device and the host device via one or more interconnect structures and/or forming one or more metal-metal bonds directly between bond pads in the upper substrate, the heat-mitigating HBM device, and the host device. In some embodiments, block 506 includes an upper substrate (e.g., a silicon interposer and/or another suitable substrate) with the communication channels with the upper surface of the heat-mitigating HBM device and an upper surface of the IO die. In some embodiments, block 506 includes various BEOL processing steps to form one or more dielectric layers and communication channels over the upper surface of the heat-mitigating HBM device and the upper surface of either the host device or the IO die.

At block 508, the process 500 includes forming a thermal interface material over the upper substrate. In various embodiments, forming the thermal interface material can include one or more deposition processes (e.g., spin coating process, chemical vapor deposition, and/or the like), attaching a premade thermal interface component to the upper substrate, and/or the like. In some embodiments, the process 500 can execute block 508 generally simultaneously with block 506. For example, the process 500 can include a deposition process after one or more BEOL processes discussed above to deposit the thermal interface material over the upper substrate.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately,” “generally,” and/or “about” are used herein to mean within at least 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device, comprising:
a base substrate;
a host device carried by the base substrate;
a heat-mitigating high-bandwidth memory (HBM) device carried by the base substrate adjacent to the host device, wherein the heat-mitigating HBM device comprises a stack of one or more memory dies and an interface die carried by the stack of one or more memory dies, and wherein the interface die includes an input/output (IO) circuit accessible through one or more bond pads on an upper surface of the interface die;
a communication substrate carried by the host device and the heat-mitigating HBM device, wherein the communication substrate comprises one or more communication channels communicably coupling the one or more bond pads on the upper surface of the interface die to the host device; and
a thermal interface material carried by the communication substrate.

2. The SiP device of claim 1 wherein:
the IO circuit is a first IO circuit;
the host device comprises:
a processing unit carried by the base substrate, the processing unit including a second IO circuit; and
a host device substrate carried by the processing unit; and
the SiP device further comprises an IO die carried by the host device and positioned between the host device and the communication substrate, the IO die including a third IO circuit communicably coupled between the second IO circuit and the one or more communication channels in the communication substrate.

3. The SiP device of claim 2 wherein the host device further comprises a plurality of first through substrate via (TSV) segments extending through the host device substrate, wherein the IO die includes a plurality of second TSV segments each coupled to a corresponding one of the plurality of first TSV segments to form a plurality of TSVs, and wherein the plurality of TSVs communicably couple the second IO circuit to the third IO circuit.

4. The SiP device of claim 1 wherein:
the IO circuit is a first IO circuit;
the host device comprises a host device substrate carried by the base substrate and a processing unit carried by the host device substrate, wherein the processing unit includes a second IO circuit accessible through one or more bond pads on a top surface of the processing unit; and
the one or more communication channels in the communication substrate are communicably coupled between the one or more bond pads on the top surface of the processing unit and the one or more bond pads on the upper surface of the interface die.

5. The SiP device of claim 4 wherein the host device substrate includes a plurality of through substrate vias (TSVs) extending from a lowermost surface of the host device to a metallization layer within the processing unit to route signals from the base substrate to the processing unit.

6. The SiP device of claim 1 wherein the heat-mitigating HBM device further comprises a power through substrate via (TSV) extending from a lowermost surface of the HBM device to a metallization layer in the interface die to provide power from the base substrate to the interface die and each of the one or more memory dies in the stack.

7. The SiP device of claim 6 wherein the metallization layer is a first metallization layer, wherein the HBM device further comprises a plurality of signal TSVs communicably coupling the interface die to each of the one or more memory dies in the stack, wherein each of the plurality of signal TSVs extend from the interface die to a second metallization layer in a lowermost memory die in the stack, and wherein the second metallization layer is a height above the lowermost surface of the HBM device.

8. The SiP device of claim 1 wherein the communication substrate further comprises a silicon interposer, and wherein the one or more communication channels are formed in the silicon interposer.

9. The SiP device of claim 1 wherein the communication substrate further comprises a plurality of dielectric layers, and wherein the one or more communication channels are formed in the plurality of dielectric layers.

10. A high-bandwidth memory (HBM) device, comprising:
a die stack having a plurality of memory dies;
an interface die carried on the die stack, wherein the interface die comprises an input/output (IO) circuit and at least one metallization layer coupled to the IO circuit; and
a plurality of through substrate vias (TSVs), wherein the plurality of TSVs includes a subset of one or more TSVs extending from the metallization layer in the interface die to a bottom surface of a lowermost memory die in the die stack, and wherein the subset of one or more TSVs is positioned to provide power to the interface die and each of the plurality of memory dies.

11. The HBM device of claim 10 wherein each of the plurality of memory dies has a generally uniform first thickness, and wherein the interface die has a second thickness larger than the first thickness.

12. The HBM device of claim 10 wherein the subset of one or more TSVs is a first subset, and wherein the plurality of TSVs further includes a second subset of one or more TSVs extending from the metallization layer in the interface die to an intermediate depth of the lowermost memory die, wherein the second subset of one or more TSVs communicably couples each of the memory dies to the interface die.

13. The HBM device of claim 10 wherein the interface die further comprises one or more bond pads at a top surface of the interface die, each of the one or more bond pads coupled to the IO circuit to provide access to the IO circuit through an uppermost surface of the HBM device.

14. A system-in-package (SiP) device, comprising:
a base substrate;
a host package integrated with the base substrate;
a heat-mitigating high-bandwidth memory (HBM) device integrated with the base substrate, wherein the heat-mitigating HBM device comprises a die stack having a plurality of memory dies and an interface die carried by the die stack, and wherein the interface die includes an input/output (IO) circuit accessible through an uppermost surface of the heat-mitigating HBM device;
an upper substrate carried by the host package and the heat-mitigating HBM device, wherein the upper substrate comprises one or more communication channels communicably coupling the IO circuit to the host package through the upper substrate; and
a thermal interface material carried by the communication substrate.

15. The SiP device of claim 14 wherein the IO circuit is a first IO circuit, and wherein the host package comprises:
a host device having a host processer and a second IO circuit coupled to the host processer;
an IO die carried by the host device, the IO die having a third IO circuit accessible through a topmost surface of the host package, wherein the third IO circuit is communicably coupled to the communication channels in the upper substrate; and
one or more through substrate vias (TSVs) extending between the second IO circuit and the third IO circuit, wherein each of the one or more TSVs includes a first segment in the host device and a second segment in the IO die.

16. The SiP device of claim 14 wherein:
the IO circuit is a first IO circuit;
the host package comprises a host substrate integrated with the base substrate and a host processer carried by the host substrate, wherein the host processer includes a second IO circuit accessible through a top surface of the host processer; and
the one or more communication channels in the upper substrate are communicably coupled between the second IO circuit and the first IO circuit.

17. The SiP device of claim 14 wherein the heat-mitigating HBM device further comprises a plurality of through substrate vias (TSVs), wherein the plurality of TSVs includes:
a first subset of one or more TSVs extending from a metallization layer in the interface die to a lowermost surface of the heat-mitigating HBM device, wherein the first subset of one or more TSVs is positioned to provide power to the interface die and each of the plurality of memory dies in the die stack; and
a second subset of one or more TSVs extending from the metallization layer in the interface die to an intermediate depth of a lowermost memory die in the die stack, wherein the second subset of one or more TSVs communicably couples each of the memory dies to the interface die.

18. The SiP device of claim 14 wherein the base substrate is a silicon interposer.

19. The SiP device of claim 14 wherein the base substrate does not include any communication channels coupled between the host package and the heat-mitigating HBM device.

20. The SiP device of claim 14 wherein the base substrate has a first thickness, and wherein the upper substrate has a second thickness greater than the first thickness.
